(19) United States
(12) Patent Application Publication
(10) Pub. No.: US 2007/0151515 A1
(43) Pub. Date: Jul. 5, 2007

(54) Multi-chamber semiconductor device fabrication apparatus comprising wafer-cooling blade

(76) Inventor: Jong-Jun Kim, Osan-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/585,264

(22) Filed: Oct. 24, 2006

(30) Foreign Application Priority Data
Jan. 4, 2006 (KR) 2006-0000814

(51) Int. Cl. C23F 1/00; C23C 16/00

(52) U.S. Cl. 118/719; 156/345.31

(57) ABSTRACT

Embodiments of the invention provide a multi-chamber semiconductor device fabrication apparatus. The invention provides a multi-chamber semiconductor device fabrication apparatus comprising a transfer chamber, a plurality of outer chambers connected to the transfer chamber, and a wafer handling and cooling mechanism comprising a wafer-cooling blade adapted to support a wafer seated on the wafer-cooling blade. In addition, the wafer handling and cooling mechanism is adapted to transfer the wafer seated on the wafer-cooling blade from an interior of the transfer chamber to a first outer chamber during a transfer period, and the wafer-cooling blade is adapted to actively cool the wafer seated on the wafer-cooling blade during the transfer period.

### BACKGROUND

1. Field of the Invention

Embodiments of the invention relate to a multi-chamber semiconductor device fabrication apparatus. In particular, embodiments of the invention relate to a multi-chamber semiconductor device fabrication apparatus comprising a wafer handling and cooling mechanism comprising a wafer-cooling blade adapted to actively cool a wafer during a transfer period.

This application claims priority to Korean Patent Application No. 10-2006-0000814, filed Jan. 4, 2006, the subject matter of which is hereby incorporated herein by reference in its entirety.

2. Description of Related Art

Recently, multi-chamber semiconductor device fabrication apparatuses capable of processing relatively large wafers, as well as multi-chamber semiconductor device fabrication apparatuses have been used in order to increase productivity in semiconductor device fabrication.

FIG. 1 illustrates a conventional multi-chamber semiconductor device fabrication apparatus. The conventional multi-chamber semiconductor device fabrication apparatus shown in FIG. 1 comprises a wafer transfer robot la disposed at the center of the conventional multi-chamber semiconductor device fabrication apparatus, and a transfer chamber 1 which is kept in a constant vacuum state, and in which wafer transfer robot la is disposed. The conventional multi-chamber semiconductor device fabrication apparatus also comprises a plurality of outer chambers that are connected to transfer chamber 1 through a plurality of slits, respectively.

Among the outer chambers are a plurality of load lock chambers 2 in which wafers wait on standby. A wafer may wait on standby in a load lock chamber 2 before being removed in order for a process to be performed on the wafer, or a wafer may wait on standby in a load lock chamber 2 after a process has already been performed on the wafer. Load lock chambers 2 are adjacent to one another and disposed on a first portion of the outer perimeter of transfer chamber 1. As illustrated in FIG. 1, the outer perimeter of transfer chamber 1 comprises a plurality of sides.

The conventional multi-chamber semiconductor device fabrication apparatus shown in FIG. 1 further comprises a plurality of process chambers 3 adjacent to one another and are disposed on a second portion of the outer perimeter of transfer chamber 1, which is opposite the first portion of the outer perimeter of transfer chamber 1. Process chambers 3 are also disposed opposite load lock chambers 2, respectively. In addition, processes such as etching or metal interconnection formation are performed in each process chamber 3. The apparatus of FIG. 1 further comprises a plurality of stripping chambers 4.

In the conventional multi-chamber semiconductor device fabrication apparatus illustrated in FIG. 1, although a wafer may be unloaded to a load lock chamber 2 after a process performed on the wafer in process chamber 3 has been completed and the wafer has been subsequently cooled, the wafer may also pass through a stripping chamber 4 (i.e., one of the plurality of stripping chambers 4) disposed between a load lock chamber 2 and a process chamber 3 around the outer perimeter of transfer chamber 1 in order to strip off photoresist patterns remaining on the wafer.

In addition, a pre-alignment chamber 5, which aligns flat zones of wafers, may be disposed on a first side of transfer chamber 1, and a cool-down chamber 6, which cools a wafer immediately after a process has been performed on the wafer, may be disposed on a second side of transfer chamber 1. In a conventional multi-chamber semiconductor device fabrication apparatus comprising a pre-alignment chamber 5 and a cool-down chamber 6, like the conventional apparatus illustrated in FIG. 1, pre-alignment chamber 5 is generally disposed between a load lock chamber 2 and a stripping chamber 4 around the outer perimeter of transfer chamber 1, and cool-down chamber 6 is also generally disposed between a load lock chamber 2 and a stripping chamber 4 around the outer perimeter of transfer chamber 1. In the apparatus illustrated in FIG. 1, the load lock chamber 2 and stripping chamber 4 between which pre-alignment chamber 5 is disposed are different from the load lock chamber 2 and stripping chamber 4 between which cool-down chamber 6 is disposed.

In a multi-chamber semiconductor device fabrication apparatus such as the one illustrated in FIG. 1, wafers are supplied one at a time from a load lock chamber 2 to pre-alignment chamber 5 using wafer transfer robot la disposed in transfer chamber 1. A wafer is aligned in pre-alignment chamber 5 and then provided to a first process chamber 3 to undergo a required process. After a process performed on the wafer in first process chamber 3 has been completed, the wafer may be moved directly to cool-down chamber 6 to be cooled, and then unloaded to a load lock chamber 2. Alternatively, the wafer may be transferred from first process chamber 3 to a first stripping chamber 4. When the wafer is transferred from first process chamber 3 to first stripping chamber 4, first stripping chamber 4 performs a stripping operation that removes photoresist patterns that remain on the wafer after a first attempt by first process chamber 3 to remove the photoresist patterns from the wafer through a process performed in first process chamber 3. The stripping process heats the wafer to a relatively high temperature, and after the stripping process, the wafer on which the stripping process has been performed is cooled via cool-down chamber 6 and is then provided to a load lock chamber 2.

In the conventional multi-chamber semiconductor device fabrication apparatus illustrated in FIG. 1, a wafer that has been heated to a relatively high temperature by a process chamber 3, or by a process chamber 3 and a stripping chamber 4, must pass through cool-down chamber 6. The amount of time needed to pass the wafer through cool-down chamber 6 is included in the total amount of time needed for the conventional apparatus of FIG. 1 to process the wafer. As the total amount of time needed to process a wafer increases, the productivity of the conventional apparatus of FIG. 1 decreases. In addition, a wafer may be exposed to contaminants such as particles as it passes through cool-down chamber 6, and that exposure to contaminants may cause process failures.

### SUMMARY OF THE INVENTION

Embodiments of the invention provide a multi-chamber semiconductor device fabrication apparatus adapted to improve the productivity of the apparatus by reducing the processing time of the apparatus by reducing the amount of time required by the apparatus to cool a wafer. Embodiments of the invention also provide a multi-chamber semiconductor device fabrication apparatus adapted to cool a wafer during a transfer period without using a separate cool-down chamber in order to reduce the amount of exposure to particles that a wafer undergoes during fabrication. Embodiments of the invention further provide a multi-chamber semiconductor device fabrication apparatus comprising at least one fewer chamber than a conventional apparatus comprising a cool-down chamber that cools wafers.

In accordance with one embodiment, the invention provides a multi-chamber semiconductor device fabrication apparatus comprising a transfer chamber, a plurality of outer chambers connected to the transfer chamber, and a wafer handling and cooling mechanism comprising a wafer-cooling blade adapted to support a wafer seated on the wafer-cooling blade. In addition, the wafer handling and cooling mechanism is adapted to transfer the wafer seated on the wafer-cooling blade from an interior of the transfer chamber to a first outer chamber during a transfer period, and the wafer-cooling blade is adapted to actively cool the wafer seated on the wafer-cooling blade during the transfer period.

In accordance with another embodiment, the invention provides a multi-chamber semiconductor device fabrication apparatus comprising a transfer chamber, a plurality of outer chambers connected to the transfer chamber, and a wafer handling and cooling mechanism comprising a wafer-cooling blade adapted to support a wafer seated on the wafer-cooling blade. Also, the wafer handling and cooling mechanism is adapted to transfer the wafer seated on the wafer-cooling blade from an interior of the transfer chamber to a first outer chamber during a transfer period, the wafer-cooling blade is adapted to actively cool the wafer seated on the wafer-cooling blade during the wafer transfer period, and the wafer-cooling blade comprises a bottom surface and a plurality of first coolant spraying nozzles disposed in the bottom surface.

In accordance with yet another embodiment, the invention provides a multi-chamber semiconductor device fabrication apparatus comprising a transfer chamber, a plurality of outer chambers connected to the transfer chamber, and a wafer handling and cooling mechanism comprising a wafer-cooling blade adapted to support a wafer seated on the wafer-cooling blade. In addition, the wafer handling and cooling mechanism is adapted to transfer the wafer seated on the wafer-cooling blade from an interior of the transfer chamber to a first outer chamber during a transfer period, the wafer-cooling blade is adapted to actively cool the wafer seated on the wafer-cooling blade during the wafer transfer period, and the wafer-cooling blade comprises a continuous wafer seating surface and a first coolant flow line disposed in the wafer-cooling blade below the continuous wafer seating surface. Also, the wafer seated on the wafer-cooling blade is seated on the continuous wafer seating surface, and first coolant is circulated in the first coolant flow line to cool the continuous wafer seating surface and thereby actively cool the wafer seated on the wafer-cooling blade.

### BRIEF DESCRIPTION OF THE DRAWINGS

Embodiments of the invention will be described herein with reference to the accompanying drawings, in which like reference symbols refer to like or similar elements throughout. In the drawings:

FIG. 1 is a plan view illustrating a conventional multi-chamber semiconductor device fabrication apparatus;

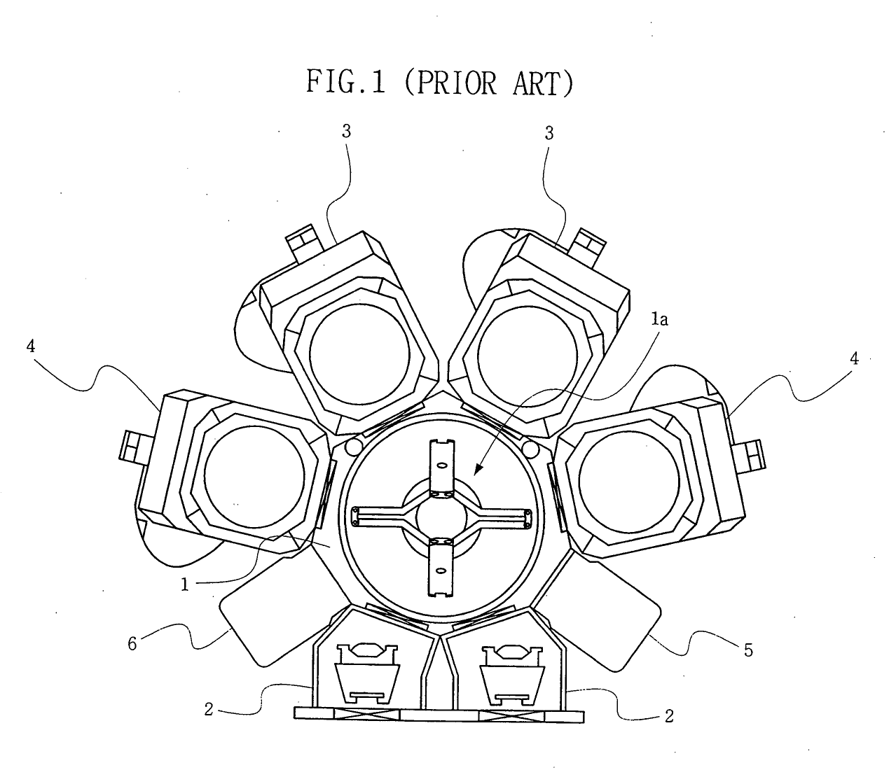

FIG. 2 is a plan view illustrating a multi-chamber semiconductor device fabrication apparatus in accordance with an embodiment of the invention;

FIG. 3 is a perspective view illustrating a wafer-cooling blade in accordance with an embodiment of the invention;

FIG. 4 is a cross-sectional view of the wafer-cooling blade of FIG. 3 taken along a line A-A of FIG. 3, and a more detailed cross-sectional view of a portion of the wafer-cooling blade;

FIG. 5 is a plan view illustrating how coolant may be sprayed through coolant spraying nozzles in accordance with an embodiment of the invention;

FIG. 6 is a block diagram illustrating coolant controlling mechanisms and a portion of a cross-sectional view of the wafer-cooling blade of FIGS. 3 through 5 in accordance with an embodiment of the invention;

FIG. 7 is a cross-sectional view of a wafer-cooling blade in accordance with an embodiment of the invention;

FIG. 8 is a block diagram schematically illustrating coolant controlling mechanisms and a portion of a cross-section view of the wafer-cooling blade in accordance with an embodiment of the invention;

FIG. 9 is a cross-sectional view illustrating a portion of a wafer-cooling blade in accordance with an embodiment of the invention; and,

FIG. 10 shows a portion of a wafer-cooling blade and illustrates a coolant flow line disposed inside of the wafer-cooling blade in accordance with an embodiment of the invention.

### DESCRIPTION OF EMBODIMENTS

A multi-chamber semiconductor device fabrication apparatus in accordance with an embodiment of the invention comprises a transfer chamber and a plurality of outer chambers connected to the transfer chamber via a plurality of slits, respectively.

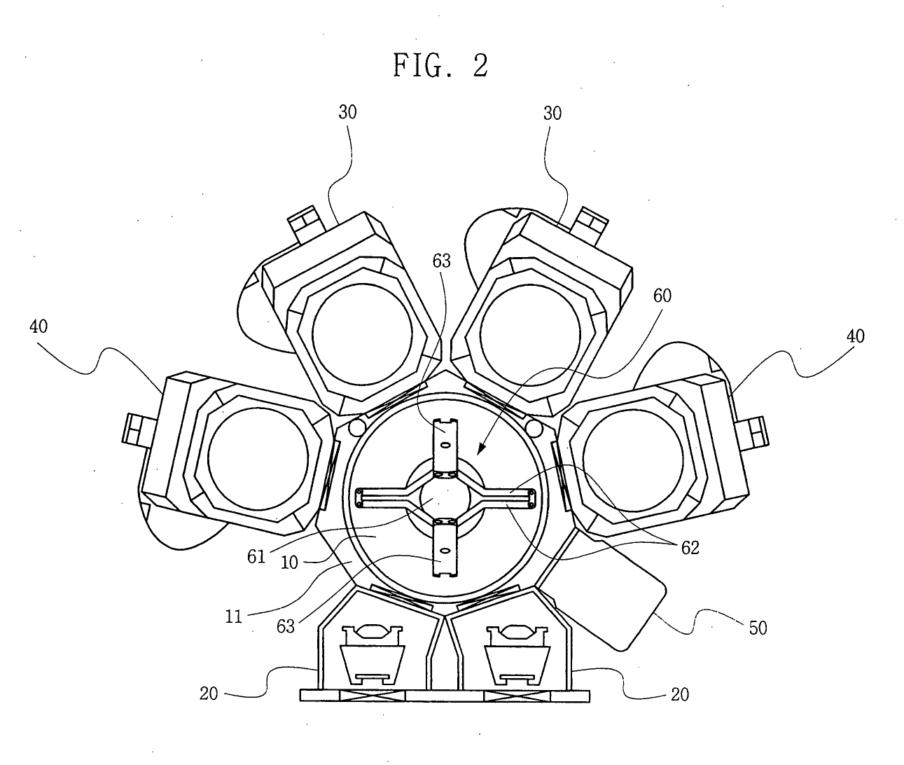

FIG. 2 illustrates a multi-chamber semiconductor device fabrication apparatus in accordance with an embodiment of the invention. Although multi-chamber semiconductor device fabrication apparatuses may be used to perform various different processes, embodiments of the invention will be described in relation to a multi-chamber semiconductor device fabrication apparatus adapted to perform an etching process, which is an exemplary process used for the purpose of describing the multi-chamber semiconductor device fabrication apparatus of FIG. 2.

The multi-chamber semiconductor device fabrication apparatus illustrated in FIG. 2 comprises a central transfer chamber 11, and a plurality of outer chambers connected to transfer chamber 11. The plurality of outer chambers comprises first and second load lock chambers 20 connected to a first portion of an outer perimeter of transfer chamber 11 (however, in general, only first load lock chamber 20 (which is the rightmost load lock chamber 20 in FIG. 2) will be referred to in the description of embodiments, and it will be referred to as “load lock chamber 20”). The plurality of outer chambers further comprises first and second process chambers 30 connected to a second portion of an outer perimeter of transfer chamber 11 opposite the first portion (however, in general, only one of first and second process chambers 30 will be referred to in the description of embodiments, and it will be referred to as “process chamber 30”). In addition, the plurality of outer chambers further comprises first and second stripping chambers 40 (however, only one of first and second stripping chambers 40 will be referred to in the description of embodiments hereafter, and it will be referred to as “stripping chamber 40”). Stripping chamber 40 is disposed between load lock chamber 20 and process chamber 30 around the outer perimeter of transfer chamber 11. The plurality of outer chambers still further comprises a pre-alignment chamber 50 disposed between load lock chamber 20 and stripping chamber 40 around the outer perimeter of transfer chamber 11. Additionally, the multi-chamber semiconductor device fabrication apparatus illustrated in FIG. 2 comprises a wafer handling and cooling mechanism 60 disposed inside transfer chamber 11.

Transfer chamber 11 is disposed in the center of the multi-chamber semiconductor device fabrication apparatus of FIG. 2, and is connected with the plurality of outer chambers through a plurality of slits, respectively. In addition, transfer chamber 11 defines an interior 10 of transfer chamber 11 (i.e., a moving space), wherein a wafer may be moved through interior 10 as the wafer is transferred between outer chambers during a transfer period. Interior 10 of transfer chamber 11 is kept in a constant vacuum state.

In the embodiment illustrated in FIG. 2, first load lock chamber 20 is connected to a first portion of the outer perimeter of transfer chamber 11 and holds wafers on standby in a cassette. In addition, first and second load lock chambers 20 are disposed near one another and operate independently. Each of first and second load lock chambers 20 is adapted store wafers in a cassette, wherein each wafer may be removed to undergo a process. Each of first and second load lock chambers 20 is also adapted to receive wafers on which a process has been performed. That is, each load lock chamber 20 may receive a plurality of wafers disposed in a cassette from outside of the multi-chamber semiconductor device fabrication apparatus of FIG. 2.

The wafers disposed in a cassette provided to a load lock chamber 20 from outside of the multi-chamber semiconductor device fabrication apparatus of FIG. 2 are generally on standby in the load lock chamber 20. While the wafers are generally on standby, wafers disposed in the cassette are individually (i.e., sequentially) removed to undergo a process. Once the process has been performed on the wafer, that wafer is returned to its original position in the cassette in the load lock chamber 20 from which it was removed.

Each load lock chamber 20 is in a standby state when a cassette is supplied to the load lock chamber 20 from outside of the multi-chamber semiconductor device fabrication apparatus of FIG. 2 or when the load lock chamber 20 transfers a cassette out of the multi-chamber semiconductor device fabrication apparatus of FIG. 2 after a process has been performed on the wafers disposed in the cassette. However, each load lock chamber 20 is kept in a vacuum state when the load lock chamber 20 is isolated from all component(s) disposed outside of the apparatus of FIG. 2 and instead communicates wafers with central transfer chamber 11. Accordingly, while load lock chamber 20 is in a standby state or a vacuum state, it may be held with a specific process atmosphere or a standby atmosphere.

Process chamber 30 is a chamber in which a semiconductor fabrication process(es) is performed on wafers in the multi-chamber semiconductor device fabrication apparatus of FIG. 2. That is, a process(es) that needs to be performed on the wafers loaded into the multi-chamber semiconductor device fabrication apparatus of FIG. 2 is performed on the wafers in process chamber 30. The interior of process chamber 30 is kept at a high temperature and kept under vacuum pressure while a process is performed therein.

Process chamber 30 is connected to a pump (not shown) which provides vacuum pressure within process chamber 30 so that it can be filled with a reaction gas required to perform a process.

As with first and second load lock chambers 20, the multi-chamber semiconductor device fabrication apparatus of FIG. 2 comprises a plurality of process chambers 30 (i.e., first and second process chambers 30). First and second process chambers 30 are disposed next to one another around the outer perimeter of transfer chamber 11. In addition, each process chamber 30 performs its process independently.

A process performed in process chamber 30 is principally performed by plasma generated by applying RF power to a reaction gas. Using the generated plasma, photoresist disposed (i.e., coated) on the surface of a wafer is etched into a desired pattern.

Generally, after an etching process has been performed on a wafer in process chamber 30, the wafer will have been heated to a temperature above a predetermined temperature and the temperature within process chamber 30 will have risen rapidly. A wafer on which process chamber 30 has been performed may be supplied directly to a load lock chamber 20, or may be supplied to stripping chamber 40 first.

Stripping chamber 40 is a chamber that is disposed between a load lock chamber 20 and process chamber 30, and a wafer on which a process has been performed by process chamber 30 may pass through stripping chamber 40. As used herein, when a first chamber is said to be disposed “between” a second chamber and a third chamber, it means that the first chamber is disposed between the second chamber and the third chamber around the outer perimeter of central transfer chamber 11 of FIG. 2 (though the first chamber is not necessarily disposed between only the second and third chambers).

After a process has been performed on a wafer in process chamber 30 and removed from process chamber 30, a predetermined pattern of photoresist may still remain on the surface of the wafer. Stripping chamber 40 is adapted to remove photoresist remaining on the wafer removed from process chamber 30. The stripping process performed in stripping chamber 40 to remove photoresist that remains on a wafer is performed by plasma, like the process performed in process chamber 30. The stripping process performed in stripping chamber 40 is performed at a temperature that is much higher than the temperature at which plasma is generated in process chamber 30. Generally, wafers are heated to a relatively high temperature of 310° C. or more through the stripping process.

After the stripping process has been performed on a wafer in stripping chamber 40, the wafer is transferred from stripping chamber 40 back into the load lock chamber 20 from which it was removed and is even placed into the position within the cassette from which it was removed.

Also, a multi-chamber semiconductor device fabrication apparatus in accordance with an embodiment of the invention comprises at least one stripping chamber 40. Preferably, a multi-chamber semiconductor device fabrication apparatus in accordance with an embodiment of the invention comprises the same number of stripping chambers 40 as process chambers 30.

Pre-alignment chamber 50 is adapted to align the flat zone of a wafer before it is loaded into process chamber 30 because the wafer needs to be loaded into process chamber 30 with the correct orientation in order for process chamber 30 to properly perform a process on the wafer. In general, the respective flat zones of the wafers are used as reference areas for aligning the wafers. A flat zone of a wafer is formed by cutting off a portion of the wafer such that the perimeter of the resulting wafer comprises a straight line segment. Using the flat zones, the wafers may always be loaded into process chamber 30 with the correct orientation (i.e., uniformly).

As described above, the flat zone alignment may be performed on a wafer before a process is performed on the wafer in process chamber 30. Alternatively, the flat zone alignment may be performed on a wafer immediately after process chamber 30 has performed a process on the wafer and before the wafer is loaded into a cassette in a load lock chamber 20.

Pre-alignment chamber 50, where the flat zone alignment is generally performed, is disposed between load lock chamber 20 and process chamber 30.

The multi-chamber semiconductor device fabrication apparatus of FIG. 2 comprises stripping chamber 40 disposed between load lock chamber 20 and process chamber 30. In addition, pre-alignment chamber 50 may be disposed between load lock chamber 20 and stripping chamber 40 (as shown in FIG. 2) or between stripping chamber 40 and process chamber 30. However, pre-alignment chamber 50 is preferably disposed between load lock chamber 20 and stripping chamber 40.

Also in the embodiment illustrated in FIG. 2, wafer handling and cooling mechanism 60 is disposed inside of transfer chamber 11 and is adapted to transfer wafers among a plurality of chambers connected to transfer chamber 11. That is, wafer handling and cooling mechanism 60 (disposed within transfer chamber 11) is adapted to load wafers into and unload wafers from each of load lock chamber 20, process chamber 30, stripping chamber 40, and pre-alignment chamber 50 of the plurality outer of chambers connected to transfer chamber 11.

Wafer handling and cooling mechanism 60 comprises a driving shaft 61 disposed in the center of transfer chamber 11 and two transfer arms 62 that are disposed opposite one another on driving shaft 61. A plurality of motors disposed at the bottom of transfer chamber 11 is adapted to rotate driving shaft 61 3600 and elevate driving shaft 61 to a predetermined height. Transfer arms 62 of wafer handling and cooling mechanism 60 are pivotally supported by driving shaft 61, are moved independently of one another, and have a constant height difference in opposite directions.

In addition, a tip of each transfer arm 62 comprises a wafer-cooling blade 63 adapted to support a wafer seated on wafer-cooling blade 63. A wafer-cooling blade 63 may be formed having one of various shapes; however, a wafer seating surface of wafer-cooling blade 63 should have a large enough area (or portions of the wafer seating surface should be spaced far enough apart) to allow a wafer to be seated on wafer-cooling blade 63 stably (i.e., safely). Also, each wafer-cooling blade 63 is preferably has a structure adapted to automatically substantially center a wafer seated on wafer-cooling blade 63.

Thus, wafer handling and cooling mechanism 60 is adapted to move wafer-cooling blade 63 linearly in a horizontal direction through the operation of a corresponding transfer arm 62, and driving shaft 61 of wafer handling and cooling mechanism 60 is adapted to rotate and move vertically to thereby rotate wafer-cooling blade 63 and move wafer-cooling blade 63 vertically. In addition, wafer-cooling blade 63 is adapted to support a wafer seated thereon. Therefore, wafer handling and cooling mechanism 60 is adapted to load wafers into and unload wafers from the outer chambers surrounding transfer chamber 11 using wafer-cooling blade 63. As used herein, the “horizontal direction” means the horizontal direction relative to the multi-chamber semiconductor device fabrication apparatus of FIG. 2, which is shown from the top, so the horizontal direction is co-planar with the page in FIG. 2. Also, as used herein, the “vertical direction” means the vertical direction relative to the multi-chamber semiconductor device fabrication apparatus of FIG. 2, which is shown from the top, so the vertical direction is perpendicular to the page in FIG. 2.

In addition, wafer-cooling blade 63 of wafer handling and cooling mechanism 60 is adapted to actively cool a wafer seated thereon.

Conventionally, wafers that have undergone etching and stripping processes in a process chamber and a stripping chamber, respectively, are then placed in a separate cool-down chamber to be cooled. However, in accordance with embodiments of the invention, wafer handling and cooling mechanism 60 comprises a wafer-cooling blade 63 so that a wafer may be cooled in a multi-chamber semiconductor device fabrication apparatus in accordance with an embodiment of the invention without being placed in a cool-down chamber. In addition, the wafer may be cooled in a multi-chamber semiconductor device fabrication apparatus in accordance with an embodiment of the invention, wherein the multi-chamber semiconductor device fabrication apparatus does not comprise a cool-down chamber.

After an etching process has been performed on a wafer in process chamber 30, as described above, when the wafer is drawn out of process chamber 30, the wafer will have a temperature of 80° C. or more. A stripping process is then performed on the wafer in stripping chamber 40. After the stripping process is performed on the wafer, when the wafer is drawn out of stripping chamber 40, it will have a temperature of 310° C. or more. As in the etching process performed in process chamber 30, the stripping process performed in stripping chamber 40 removes photoresist from a wafer by plasma.

If one or more wafers that have been heated to a relatively high temperature as described above are loaded into a cassette disposed in a load lock chamber 20 at that temperature, the wafer(s) and the cassette may be deformed by the heat. Such deformation may cause a process failure(s) to occur in a subsequent process. Accordingly, embodiments of the invention provide a wafer handling and cooling mechanism 60 adapted to cool a wafer to a predetermined temperature (i.e., sufficiently cool a wafer) as it transfers the wafer to a load lock chamber 20, that is, during a transfer period. As used herein, a “transfer period” is a period of time during which wafer handling and cooling mechanism 60 moves a wafer from one outer chamber, through interior 10 of transfer chamber 11, and to another outer chamber. In addition, during a transfer period, wafer handling and cooling mechanism 60 is adapted to move a wafer from one outer chamber into interior 10 of transfer chamber 11 during a first portion of the transfer period, wafer handling and cooling mechanism 60 is adapted to actively cool the wafer during a second portion of the transfer period, and wafer handling and cooling mechanism 60 is adapted to move the wafer from interior 10 of transfer chamber 11 to another outer chamber during a third portion of the transfer period.

Wafer handling and cooling mechanism 60 comprises a wafer-cooling blade 63 that may be embodied in various different forms. In accordance with one embodiment, wafer-cooling blade 63 may be adapted to directly cool a wafer seated thereon, and in accordance with another embodiment, wafer-cooling blade 63 may be adapted to both directly and indirectly cool a wafer seated thereon.

When wafer-cooling blade 63 directly cools a wafer seated thereon, coolant contacts the wafer directly and the coolant is preferably provided in a gaseous state. In addition, the gaseous coolant is preferably helium. In addition, when wafer-cooling blade 63 directly cools a wafer seated thereon, wafer-cooling blade 63 may spray coolant directly onto an upper surface of the wafer or directly onto an upper surface and a lower surface of the wafer.

When coolant is sprayed directly onto the top surface of a wafer seated on wafer-cooling blade 63, the top surface of the wafer should be disposed below nozzles that spray coolant. That is, to cool a wafer seated on wafer-cooling blade 63 by spraying coolant onto the top surface of the wafer, the coolant gas should be sprayed toward the top surface of the wafer from a location above the top surface of the wafer.

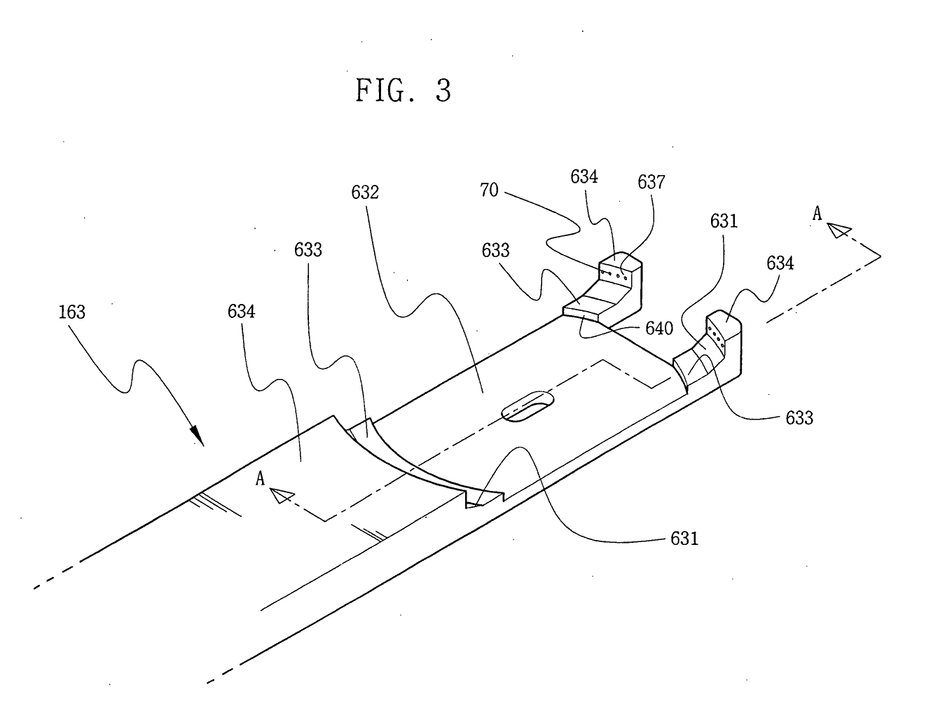

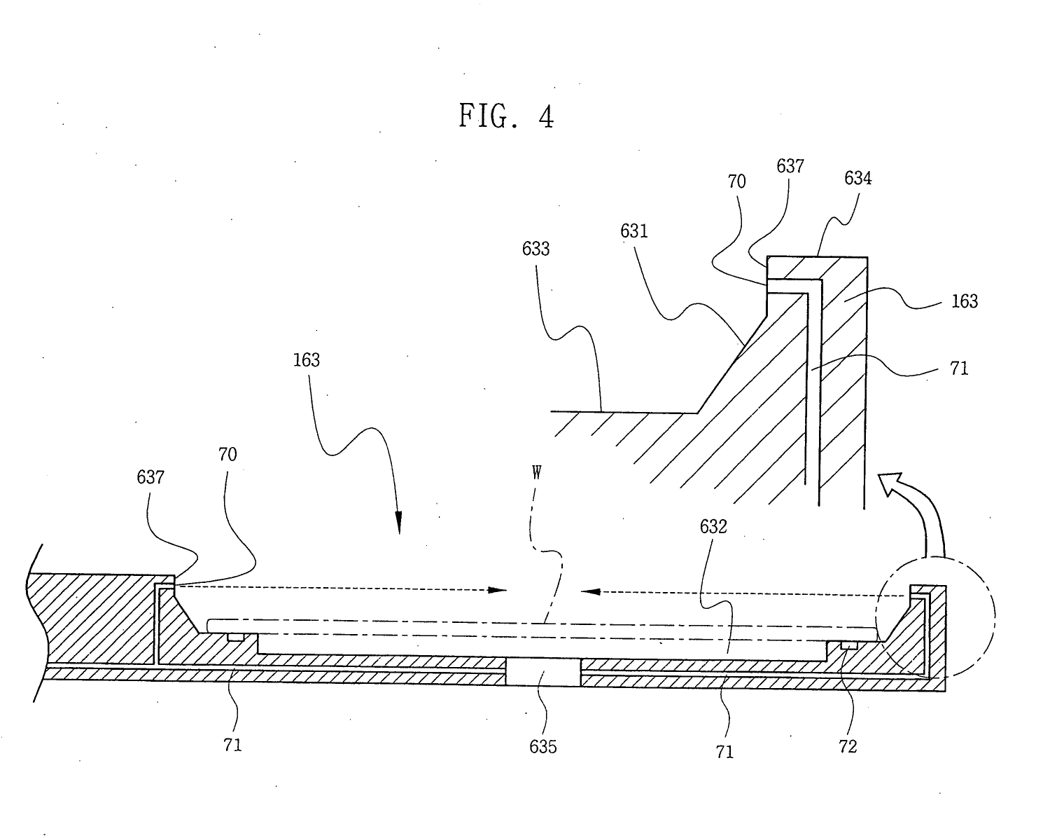

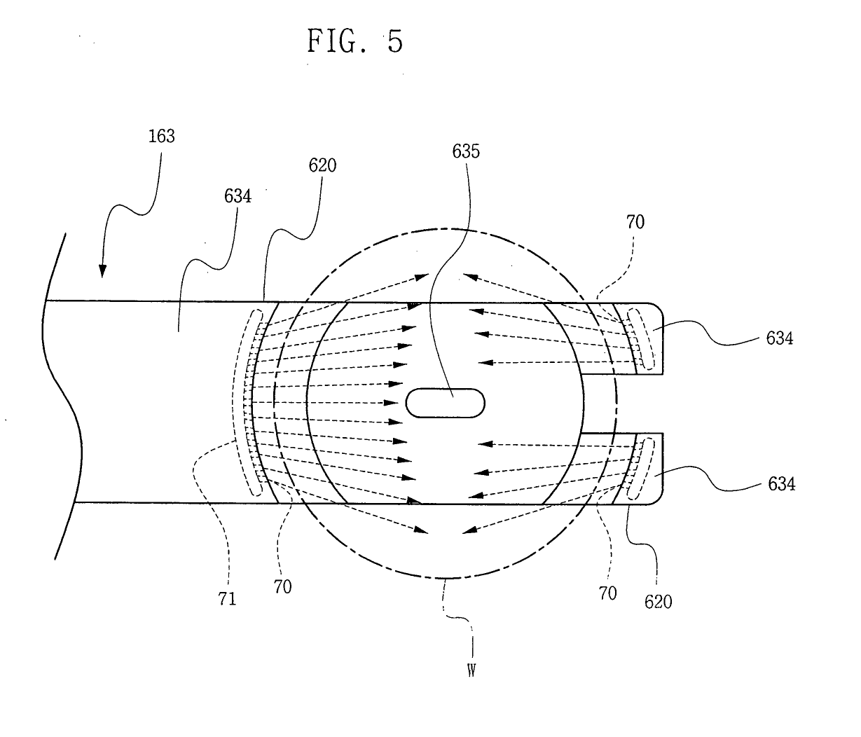

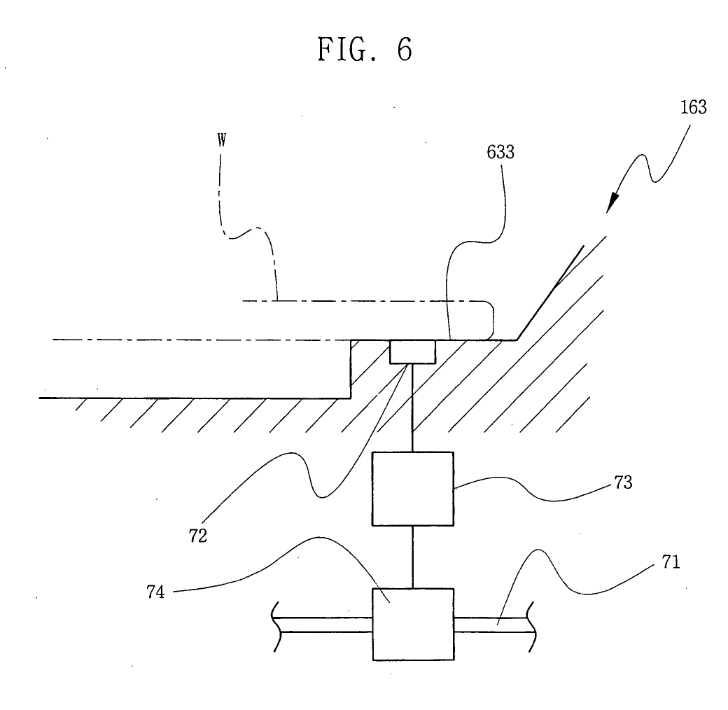

FIG. 3 is a perspective view illustrating a wafer-cooling blade 163 in accordance with an embodiment of the invention, and FIG. 4 is a cross-sectional view of wafer-cooling blade 163 of FIG. 3 taken along a line A-A of FIG. 3, and a more detailed cross-sectional view of a portion of wafer-cooling blade 163. FIG. 5 is a plan view illustrating how coolant may be sprayed through coolant spraying nozzles 70 in accordance with an embodiment of the invention, and FIG. 6 is a block diagram illustrating coolant controlling mechanisms and a portion of a cross-sectional view of wafer-cooling blade 163 of FIGS. 3 through 5 in accordance with an embodiment of the invention. In addition, wafer-cooling blade 163 of FIGS. 3 through 6 is an embodiment of wafer-cooling blade 63 of FIG. 2.

In the embodiment illustrated in FIGS. 3 through 6, wafer-cooling blade 163 is part of a wafer handling and cooling mechanism, though only wafer-cooling blade 163 is shown in FIGS. 3 through 6. Wafer-cooling blade 163 comprises a wafer placement region in which a wafer W may be seated, and comprises a plurality of coolant spraying nozzles 70. The wafer placement region comprises a groove 632, a non-continuous wafer seating surface 633, and side surfaces 631.

Wafer-cooling blade 163 comprises a plurality of extending parts 634, wherein each extending part 634 comprises an inner surface 637 and coolant spraying nozzles 70 are disposed in each inner surface 637. In addition, in each inner surface 637, adjacent coolant spraying nozzles 70 disposed in that inner surface 637 are separated from one another at regular intervals. Wafer-cooling blade 163 further comprises side surfaces 631 surrounding groove 632. Groove 632 is defined by vertical edges 640 of portions of non-continuous wafer seating surface 633 and edges of wafer-cooling blade 163, and wafer W may be placed over groove 632. Each side surface 631 forms a slope in which, for each side surface 631, an upper side of the side surface 631 intersects with a corresponding inner surface 637, and an opposite, lower side of the side surface 631 intersects with a corresponding portion of non-continuous wafer seating surface 633. In addition, side surfaces 631 slope downwards towards the center of the wafer placement region. Thus, when a wafer W is seated off-center on wafer-cooling blade 163 (with respect to the center of the wafer placement region), the respective slopes of side surfaces 631 allow wafer W to substantially center itself with respect to the center of the wafer placement region.

In addition, side surfaces 631 and edges of wafer-cooling blade 163 define an inner space. That is, in wafer-cooling blade 163, an inner space is partially defined by side surfaces 631 and partially defined by edges of wafer-cooling blade 163. The lower sides of side surfaces 631 define a circle and partially define a lower portion of the inner space, which is a portion of the circle. Lower sides of side surfaces 631 that are opposite one another across groove 632 are separated by a distance equal to the diameter of the circle, and the diameter of the circle is greater than the diameter of wafer W. In addition, the upper sides of side surfaces 631 partially define an upper portion of the inner space. The inner space also comprises the space between the upper and lower portions of the inner space.

In wafer-cooling blade 163, the lower ends of side surfaces 631 terminate where they meet corresponding portions of non-continuous wafer seating surface 633, and each portion of non-continuous wafer seating surface 633 extends horizontally (i.e., in a direction parallel with a bottom surface of groove 632) towards the center of groove 632 and comprises an inner vertical surface 640. For each inner vertical surface 640, at least a portion of the inner vertical surface 640 is disposed opposite at least a portion of another inner vertical surface 640 of wafer-cooling blade 163. In addition, wafer W may be seated on non-continuous wafer seating surface 633 (i.e., a portion of wafer W may be supported by each portion of non-continuous wafer seating surface 633).

In the embodiment illustrated in FIGS. 3 through 6, and as shown in FIGS. 3 and 4, each extending part 634 of wafer-cooling blade 163 extends above an upper side of a corresponding side surface 631 with a predetermined height. In addition, a plurality of coolant spraying nozzles 70 is disposed in inner surface 637 of each extending part 634. As illustrated in FIGS. 3 and 4, side surfaces 631 are each sloped and terminate at a corresponding inner surface 637 that extends vertically. Alternatively, each side surface 631 and its corresponding inner surface 637 may extend continuously and with a constant slope from a corresponding portion of non-continuous wafer seating surface 633 to an upper surface of a corresponding extending part 634.

Also, in the embodiment illustrated in FIGS. 3 through 6, each of inner surfaces 637 and side surfaces 631 is curved.

Referring to FIG. 4, coolant spraying nozzles 70 disposed in inner surfaces 637 are all disposed above the upper surface of a wafer W seated on wafer-cooling blade 163. When coolant spraying nozzles 70 are disposed above the upper surface of wafer W seated on wafer-cooling blade 163, coolant is preferably sprayed through coolant spraying nozzles 70 at a slight downward angle.

In the embodiment illustrated in FIGS. 3 to 6, a wafer W is seated on non-continuous wafer seating surface 633 of wafer-cooling blade 163 (see FIG. 4) and is cooled by coolant sprayed through coolant spraying nozzles 70, which are disposed in inner surfaces 637 of extending parts 634. That is, wafer-cooling blade 163 is adapted to support a wafer W that is seated on wafer-cooling blade 163, and is adapted to actively cool wafer W by spraying coolant through coolant spraying nozzles onto wafer W. In addition, when wafer W is cooled by coolant sprayed through coolant spraying nozzles 70 at a slight downward angle, the coolant that is sprayed on wafer W may apply pressure to wafer W and press wafer W to non-continuous wafer seating surface 633, which may hold wafer W to wafer-cooling blade 163. Thus, when coolant is sprayed on wafer W in the manner described above, wafer-cooling blade 163 may thereby transfer wafer W more stably than when coolant is not sprayed on wafer W in the manner described above. In addition, FIG. 4 illustrates a wafer sensing hole 635.

In the embodiment illustrated in FIGS. 3 through 6, and as illustrated in FIG. 5, coolant spraying nozzles 70 disposed in inner surfaces 637 of extending parts 634 are adapted to spray coolant over the entire top surface of wafer W. In addition, first and second groups of coolant spraying nozzles 70 are disposed on opposite sides of groove 632 (i.e., are separated by groove 632).

Each coolant spraying nozzle 70 disposed in an inner surface 637 of an extending part 634 sprays coolant at a predetermined angle and is adapted to cool a predetermined wafer area of wafer W. As used herein, the “wafer area” of a coolant spraying nozzle is the portion of the wafer being cooled upon which the coolant sprayed by the coolant spraying nozzle has a cooling effect. That is, the portion of the wafer on which a coolant spraying nozzle sprays coolant is the “wafer area” of that coolant spraying nozzle. In addition, some wafer areas partially overlap with one another. Also, portions of the outer edge of wafer W can be cooled using coolant spraying nozzles 70 that are disposed in the outermost portions of inner surfaces 637 (i.e., coolant spraying nozzles 70 disposed nearest side edges 620 of wafer-cooling blade 163) to spray coolant on wafer W.

Referring to FIG. 6, in the embodiment illustrated in FIGS. 3 through 6, a coolant flow line 71 disposed in wafer-cooling blade 163 supplies coolant to be sprayed to each coolant spraying nozzle 70. Coolant flow line 71 may be a pipe buried in wafer-cooling blade 163. Alternatively, coolant flow line 71 may be formed integrally within wafer-cooling blade 163 (i.e., formed as a part of the structure of wafer-cooling blade 163 without a separate element such as a pipe being buried in wafer-cooling blade 163). Also, a temperature sensor 72 adapted to sense the temperature of wafer W is disposed in a portion of non-continuous wafer seating surface 633 on which wafer W is seated.

Referring to FIG. 6, temperature sensor 72 senses the temperature of wafer W and provides a temperature signal to an apparatus controller 73 in accordance with the sensed temperature. Apparatus controller 73 is adapted t control pump 74, which is adapted to selectively provide coolant to coolant spraying nozzles 70 (of FIGS. 3 to 5) and is adapted to control the pressure at which coolant is provided to coolant spraying nozzles 70. Thus, because apparatus controller 73 is adapted to control pump 74, apparatus controller 73 is adapted to control whether or not coolant is provided to coolant spraying nozzles 70 and is adapted to control the pressure at which coolant is supplied to coolant spraying nozzles 70, each in accordance with the temperature of wafer W. As an example of an operation of apparatus controller 73, the higher the temperature of wafer W, as sensed by temperature sensor 72, the greater the pressure with which apparatus controller 73 causes pump 74 to pump coolant.

The spraying of coolant, as controlled by apparatus controller 73, is performed while a wafer W is being transferred from stripping chamber 40 (after a stripping process has been performed on wafer W) to load lock chamber 20 by wafer handling and cooling mechanism 60 (see FIG. 2).

That is, when a process is performed on wafer W in process chamber 30, and then a stripping process is performed on wafer W in a stripping chamber 40, those processes heat wafer W to a relatively high temperature. While heated wafer W is transferred from stripping chamber 40 to a load lock chamber 20 by wafer handling and cooling mechanism 60 after the stripping process has been performed, coolant gas is sprayed directly onto wafer W, which is seated on wafer-cooling blade 163 of wafer handling and cooling mechanism 60, through coolant spraying nozzles 70 in order to cool wafer W to an appropriate temperature.

In particular, apparatus controller 73 controls the amount of pressure with which coolant is provided to coolant spraying nozzles 70 (which is related to the pressure at which coolant spraying nozzles 70 spray coolant) in accordance with the temperature of wafer W (as sensed by temperature sensor 72) so that, once wafer W is cooled, the temperature of wafer W can be kept below a predetermined temperature, i.e., about 80° C.

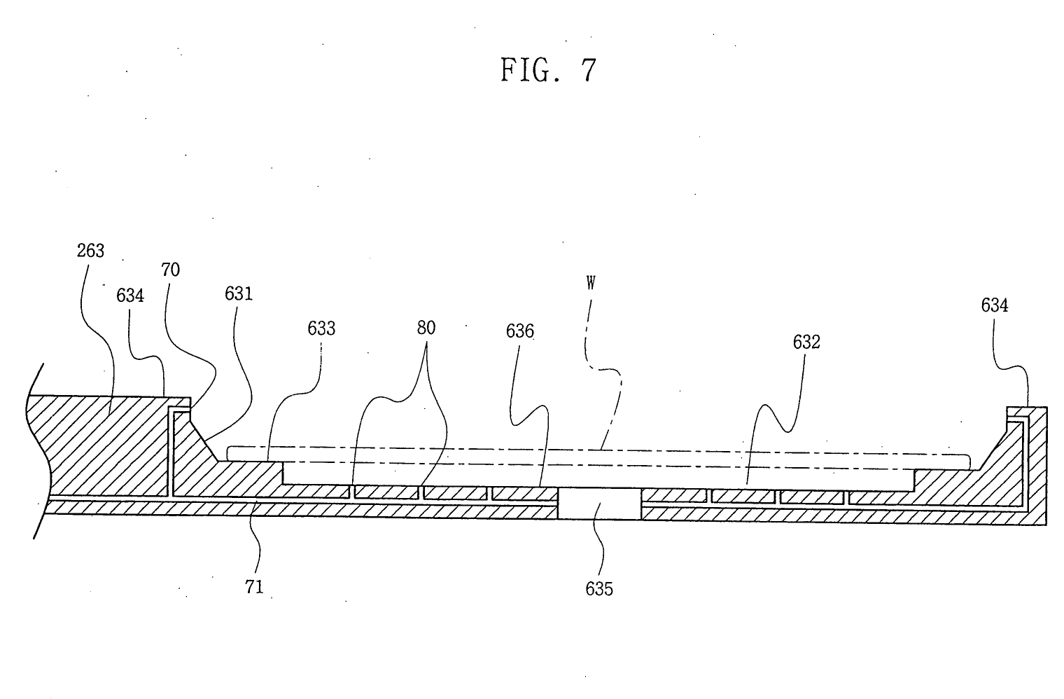

FIG. 7 is a cross-sectional view of a wafer-cooling blade 263 in accordance with an embodiment of the invention. In addition, wafer-cooling blade 263 is an embodiment of wafer-cooling blade 63 of FIG. 2. In the embodiment illustrated in FIG. 7, wafer-cooling blade 263 is adapted to spray coolant onto an upper surface of a wafer W seated on wafer-cooling blade 263 through coolant spraying nozzles 70 disposed in extending parts 634 to cool wafer W, and is adapted to spray coolant through coolant spraying nozzles 80 onto a lower surface of wafer W simultaneously in order to further promote the cooling of wafer W. Thus, wafer-cooling blade 263 is adapted to actively cool wafer W. In addition, wafer-cooling blade 263 is adapted to support a wafer W seated on wafer-cooling blade 263.

In the embodiment illustrated in FIG. 7, wafer-cooling blade 263 is adapted to spray coolant onto the upper surface of wafer W in substantially the same way as wafer-cooling blade 163 of the embodiment illustrated in FIGS. 3 through 6, and using substantially the same structures as wafer-cooling blade 163 of the embodiment illustrated in FIGS. 3 through 6. Also, in the embodiment illustrated in FIG. 7, a plurality of coolant spraying nozzles 80 are disposed in a bottom surface 636 of wafer-cooling blade 263. Bottom surface 636 is disposed below the bottom surface of a wafer W seated on non-continuous wafer seating surface 633 of wafer-cooling blade 263 and below an upper surface of each portion of non-continuous wafer seating surface 633.

Also in the embodiment illustrated in FIG. 7, the portions of non-continuous wafer seating surface 633 of wafer-cooling blade 263 collectively form portions of an incomplete ring having an inner diameter and an outer diameter. The outer diameter of non-continuous wafer seating surface 633 (i.e., the outer diameter of the incomplete ring formed by non-continuous wafer seating surface 633) is larger than the diameter of a wafer W seated on non-continuous wafer seating surface 633 so that wafer W can be seated on non-continuous wafer seating surface 633 stably (i.e., safely). In addition, the inner diameter of non-continuous wafer seating surface 633 is smaller than the diameter of wafer W. Also, a portion of wafer-cooling blade 263 that is disposed inside of the inner diameter of wafer seating surface 633 is disposed below wafer seating surface 633 (i.e., is recessed) and thus forms bottom surface 636 of wafer-cooling blade 263. Accordingly, when a wafer W is placed on non-continuous wafer seating surface 633, the bottom surface of wafer W is separated from bottom surface 636 of wafer-cooling blade 263. In addition, a wafer sensing hole 635 that extends vertically is disposed in a central portion of bottom surface 636.

Although the coolant sprayed through coolant spraying nozzles 80 disposed in bottom surface 636 may be provided to coolant spraying nozzles 80 through the same coolant flow line 71 that provides coolant to coolant spraying nozzles 70 (which spray coolant onto the upper surface of wafer W), coolant is preferably provided to coolant spraying nozzles 80 through a coolant supply line separate from coolant flow line 71.

In addition, coolant is preferably supplied onto the upper surface of wafer W at a pressure higher than the pressure with which coolant is sprayed onto the bottom surface of wafer W. If coolant is spayed onto the bottom surface of wafer W at a pressure greater than or equal to the pressure with which coolant is sprayed onto the upper surface of wafer W, wafer W may be lifted from wafer-cooling blade 263 (i.e., lifted from non-continuous wafer seating surface 633) and not rest on wafer-cooling blade 263 stably. As a result, wafer W may be removed from wafer-cooling blade 263 or severely misaligned, each of which is a problem for the multi-chamber semiconductor device fabrication apparatus comprising wafer-cooling blade 263.

Accordingly, in order to hold wafer W on wafer-cooling blade 263 stably, the pressure with which coolant is sprayed onto the upper surface of wafer W is preferably greater than the pressure at which coolant is sprayed onto the bottom surface of wafer W.

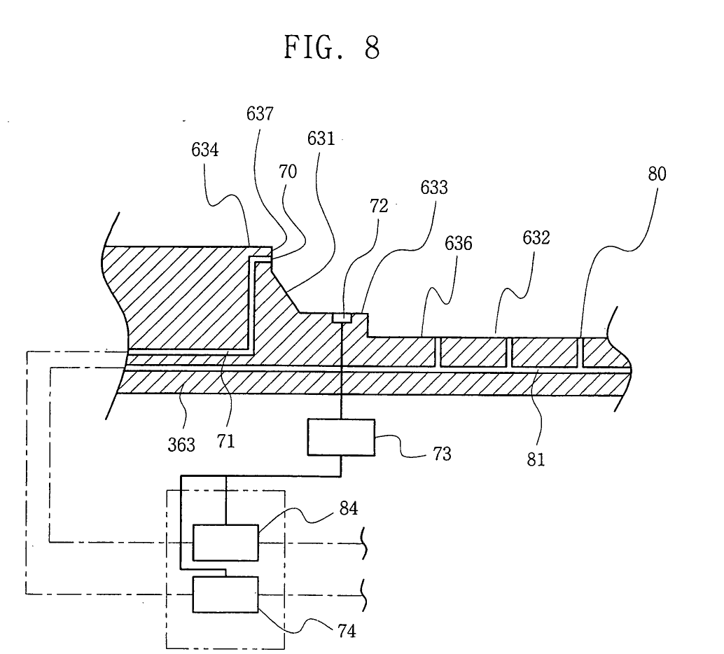

FIG. 8 is a block diagram schematically illustrating coolant controlling-mechanisms and a portion of a cross-sectional view of a wafer-cooling blade 363, in accordance with an embodiment of the invention, wherein wafer-cooling blade 363 simultaneously sprays coolant onto upper and lower surfaces of a wafer W (not shown) to thereby actively cool the wafer relatively rapidly. In addition, wafer-cooling blade 363 of FIG. 8 is an embodiment of wafer-cooling blade 63 of FIG. 2. In the embodiment illustrated in FIG. 8, wafer-cooling blade 363 is adapted to support a wafer W seated on wafer-cooling blade 363, and the coolant that is sprayed on the upper surface of wafer W seated on non-continuous wafer seating surface 633 is pumped by a first pump 74. First pump 74 pumps coolant through a first coolant flow line 71 to coolant spraying nozzles 70. First coolant flow line 71 is at least partially disposed in extending part 634 of wafer-cooling blade 363. In addition, coolant spraying nozzles 70 are disposed in an inner surface 637 of an extending part 634 and spray the coolant onto the upper surface of wafer W. However, the coolant that is sprayed on a lower surface of wafer W is pumped by a second pump 84. Second pump 84 pumps coolant through a second coolant flow line 81 to coolant spraying nozzles 80. A portion of second coolant flow line 81 is disposed in a portion of wafer-cooling blade 363 that is disposed below bottom surface 636 of wafer-cooling blade 363. In addition, coolant spraying nozzles 80 are disposed in a bottom surface 636 of wafer-cooling blade 163 and spray the coolant onto the lower surface of wafer W. Thus, in the embodiment illustrated in FIG. 8, because the coolant sprayed onto the upper surface of wafer W and the coolant sprayed onto the lower surface of wafer W are pumped by different pumps (i.e., first and second pumps 74 and 84, respectively) and provided to corresponding nozzles through different lines (i.e., first and second coolant flow lines 71 and 81, respectively), the coolant sprayed onto the upper surface of wafer W may be sprayed with a different pressure than the coolant sprayed onto the lower surface of wafer W.

Specifically, apparatus controller 73 controls first pump 74, which controls the pressure with which coolant is supplied through first coolant flow line 71 to coolant spraying nozzles 70, which spray the coolant onto the upper surface of wafer W. Additionally, apparatus controller 73 controls second pump 84, which controls the pressure with which coolant is supplied through second coolant flow line 81 to coolant spraying nozzles 80, which spray the coolant onto the lower surface of wafer W. Apparatus controller 73 also controls of each of first and second pumps 74 and 84 in accordance with a temperature signal received from temperature sensor 72 disposed in non-continuous wafer seating surface 633 of wafer-cooling blade 363 on which wafer W is seated.

Thus, one pump is used to control the pressure with which coolant is sprayed onto the upper surface of a wafer W and another pump is used to control the pressure with which coolant is sprayed onto the lower surface of wafer W, so the pressure with which coolant is sprayed onto the upper surface of a wafer W may be different from the pressure with which coolant is sprayed onto the lower surface of wafer W. In particular, wafer-cooling blade 363 may spray coolant onto the upper surface of wafer W with a higher pressure than the pressure with which it sprays coolant onto the lower surface of wafer W. If wafer-cooling blade 363 sprays coolant onto the upper surface of wafer W at a higher pressure than the pressure with which coolant is sprayed onto the lower surface of wafer W, wafer W can be held to wafer-cooling blade 363 stably while coolant is simultaneously sprayed onto the upper and lower surfaces of wafer W. Thus, wafer W can be stably held to wafer-cooling blade 363 while wafer-cooling blade 363 simultaneously sprays coolant onto the upper and lower surfaces of wafer W to thereby cool the wafer relatively rapidly.

In accordance with another embodiment of the invention, a wafer can be cooled relatively rapidly using a wafer-cooling blade adapted to cool a wafer seated thereon by both directly and indirectly cooling the wafer. A wafer-cooling blade adapted to indirectly cool a wafer seated thereon is adapted to cool the wafer-cooling blade itself to thereby cool a lower surface of a wafer that is making contact with the wafer-cooling blade.

In accordance with an embodiment of the invention, a wafer-cooling blade adapted to indirectly cool a wafer seated on the wafer-cooling blade comprises a nearly continuous wafer seating surface that almost completely and continuously fills the portion of the wafer-cooling blade disposed inside of the side surfaces of the wafer-cooling blade (i.e., the wafer seating surface is not recessed, though it may comprise a wafer sensing hole). Thus, a lower surface of the wafer makes contact with substantially all of the nearly continuous wafer seating surface. In addition, the continuous wafer seating surface is cooled to thereby cool the wafer with which it makes contact. However, a wafer cannot be cooled rapidly using the indirect cooling method alone.

Accordingly, an embodiment of the invention provides wafer-cooling blade adapted to both directly and indirectly cool a wafer. The wafer-cooling blade adapted to both directly and indirectly cool a wafer is adapted to spray coolant onto an upper surface of a wafer seated on the wafer-cooling blade to thereby directly cool the wafer. In addition, as described above with reference to a wafer-cooling blade adapted to indirectly cool a wafer seated thereon, a lower surface of the wafer seated on the wafer-cooling blade makes contact with substantially all of a nearly continuous wafer seating surface of the wafer-cooling blade, and the nearly continuous wafer seating surface is cooled in order to cool the lower surface of the wafer and thereby indirectly cool the wafer.

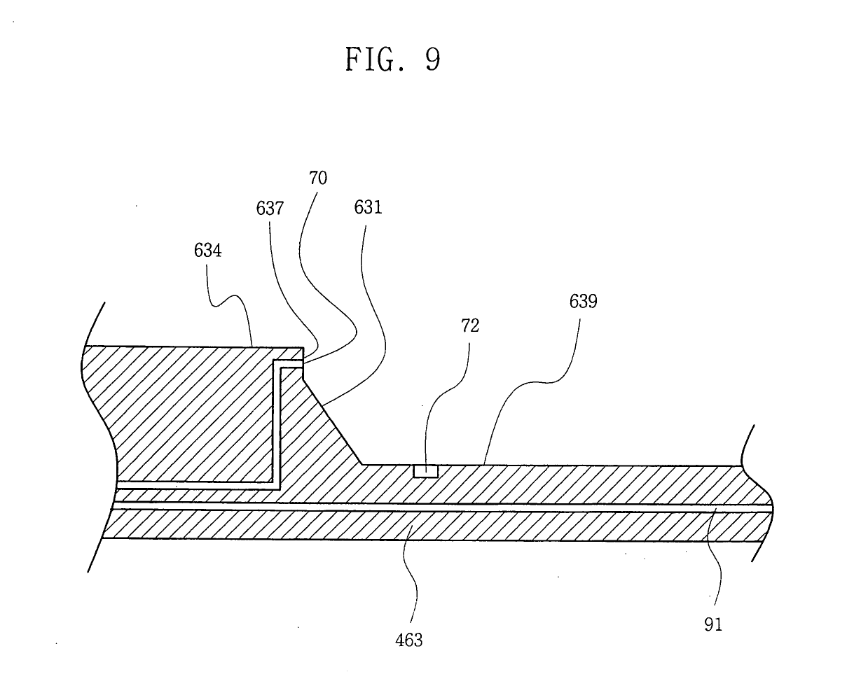

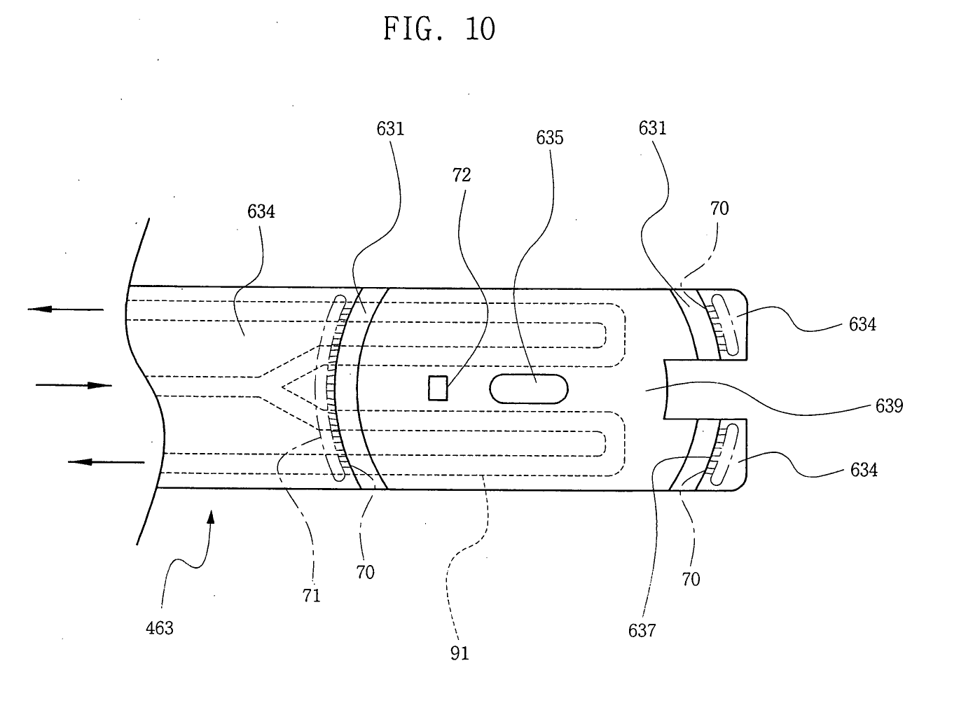

FIG. 9 is a cross-sectional view illustrating a portion of a wafer-cooling blade 463 adapted to both directly and indirectly cool a wafer seated on wafer-cooling blade 463 in accordance with an embodiment of the invention. FIG. 10 shows wafer-cooling blade 463 and illustrates a second coolant flow line 91 disposed inside of wafer-cooling blade 463 in accordance with an embodiment of the invention. In addition, wafer-cooling blade 463 of FIGS. 9 and 10 is an embodiment of wafer-cooling blade 63 of FIG. 2.

In the embodiment illustrated in FIGS. 9 and 10, wafer-cooling blade 463 is adapted to support a wafer seated on wafer-cooling blade 463, and is adapted to actively cool a wafer seated thereon both directly and indirectly. Wafer-cooling blade 463 is adapted to directly cool a wafer seated on continuous wafer seating surface 639 by spraying coolant onto an upper surface of the wafer, and is adapted to indirectly cool the wafer by cooling a lower surface of the wafer by cooling continuous wafer seating surface 639, wherein the lower surface of the wafer makes contact with substantially all of continuous wafer seating surface 639. Though continuous wafer seating surface 639 comprises a wafer sensing hole 635 and thus is not completely continuous, it is nearly continuous, so it will be referred to herein as a “continuous wafer seating surface 639” for convenience of description.

Referring to FIGS. 9 and 10, wafer-cooling blade 463 comprises side surfaces 631, extending parts 634 that extend upwardly from side surfaces 631, and a plurality of spraying nozzles 70 disposed in inner surfaces 637 of extending parts 634. Coolant spraying nozzles 70 of wafer-cooling blade 463 sprays coolant at a downward angle onto the upper surface of a wafer seated on wafer-cooling blade 463 to cool the wafer.

Wafer areas of coolant spraying nozzles 70 overlap one another and coolant spraying nozzles 70 spray coolant downwardly at the same (i.e., a constant) angle, so coolant spraying nozzles 70 spray coolant onto the upper surface of wafer W uniformly. Thus, wafer-cooling blade 463 can spray coolant onto the entire upper surface of wafer W uniformly in order to cool wafer W.

Unlike the direct cooling method by which wafer-cooling blade 463 cools a wafer by bringing the wafer into direct contact with coolant, an indirect cooling method cools continuous wafer seating surface 639 on which the wafer W is seated, wherein wafer-cooling blade 463 on which the wafer is seated is formed from a material having excellent heat conductivity.

To promote indirect cooling of a wafer seated on wafer-cooling blade 463, the amount of the surface area of the wafer that makes contact with continuous wafer seating surface 639 is preferably relatively large. Thus, continuous wafer seating surface 639 may nearly fill the entire area inside of side surfaces 631. That is, continuous wafer seating surface 639 may fill the entire area inside of side surfaces 631 except for the area in which wafer sensing hole 635 is disposed. Alternatively, continuous wafer seating surface 639 of wafer-cooling blade 463 may be viewed as a bottom surface that nearly fills the entire area inside of side surfaces 631, wherein a wafer is seated on and makes contact with the bottom surface, wherein the bottom surface is cooled to cool the wafer.

Wafer-cooling blade 463 may be formed from an aluminum alloy or a stainless steel alloy. Also, second coolant flow line 91 formed in wafer-cooling blade 463 below continuous wafer seating surface 639 may be formed having one of various shapes.

In the embodiment illustrated in FIG. 10, wafer-cooling blade 463 comprises second coolant flow line 91 adapted to circulate coolant through an area beneath continuous wafer seating surface 639, and coolant spraying nozzles 70 disposed in inner surfaces 637 of extending parts 634 that extend upwards from upper ends of side surfaces 631 of wafer-cooling blade 463. Coolant is supplied to coolant spraying nozzles 70 through a first coolant flow line 71, which is separate from second coolant flow line 91. In addition, gaseous coolant sprayed on a wafer seated on wafer-cooling blade 463 in order to directly cool the wafer may also be used as the coolant used to cool continuous wafer seating surface 639; however, a liquid coolant may be used to cool continuous wafer seating surface 639 more efficiently.

In the embodiment illustrated in FIG. 10, a first pump (not shown), like first pump 74 of FIG. 8, pumps coolant to be sprayed through a first coolant flow line 71 to coolant spraying nozzles 70. The coolant supplied to cool continuous wafer seating surface 639 can be continuously circulated in second coolant flow line 91 by driving a second pump (not shown) that is different than the first pump. Additionally, the respective pressures with which the coolant is supplied to first and second coolant flow lines 71 and 91 is controlled by an apparatus controller (not shown) in accordance with a temperature sensed by temperature sensor 72, which is attached to continuous wafer seating surface 639.

Thus, when the lower surface of a wafer seated on wafer-cooling blade 463 is cooled using continuous wafer seating surface 639 of wafer-cooling blade 463, and the upper surface of the wafer is cooled using coolant sprayed through coolant spraying nozzles 70, the wafer can be cooled to a desired temperature in a relatively short amount of time.

In accordance with embodiments of the invention, a wafer-cooling blade actively cools a wafer seated on the wafer-cooling blade during a transfer period, which is the relatively short period of time during which the wafer passes through a transfer chamber as it is being transferred from a process chamber or a stripping chamber to a load lock chamber. Accordingly, embodiments of the invention are adapted to sufficiently cool a wafer during the relatively short period of time during which the wafer is transferred to a load lock chamber from a process chamber or a stripping chamber after a process has been performed on the wafer in at least one of the process and stripping chambers.

When a wafer-cooling blade is able to sufficiently cool a wafer as it is being transferred between chambers, as described previously, the wafer does not need to pass through a conventional cool-down chamber, so the cool-down chamber may be omitted in a multi-chamber semiconductor device fabrication apparatus, in accordance with an embodiment of the invention, that comprises a wafer-cooling blade. Thus, a multi-chamber semiconductor device fabrication apparatus in accordance with an embodiment of the invention may comprise fewer chambers than the conventional multi-chamber semiconductor device fabrication apparatus. Also, since a separate wafer cooling process can be omitted, the fabrication process as a whole can be performed faster.

In addition, in accordance with embodiments of the invention, since coolant is sprayed directly onto the upper surface of the wafer being cooled, the surface of the wafer on which patterns are formed can always be kept clean.

In accordance with embodiments of the invention, a multi-chamber semiconductor device fabrication apparatus may comprise a wafer handling and cooling mechanism comprising a wafer-cooling blade adapted to directly cool, or directly and indirectly cool, a wafer seated on the wafer-cooling blade. The wafer-cooling blade is adapted to spray coolant directly onto an upper surface of a wafer seated on the wafer-cooling blade in order to cool the wafer. In addition, the wafer-cooling blade may be adapted to spray coolant onto a lower surface of the wafer from a bottom surface of the wafer-cooling blade in order to cool the wafer, or the wafer-cooling blade may also be adapted to circulate coolant below a continuous wafer seating surface in order to cool the continuous wafer seating surface and thereby cool a bottom surface of the wafer that makes contact with the wafer seating surface.

Thus, in accordance with embodiments of the invention, a wafer-cooling blade can cool a wafer seated on the wafer-cooling blade rapidly by using an apparatus controller to appropriately control, in accordance with a temperature sensed by a temperature sensor, when coolant is provided to coolant flow lines of the wafer-cooling blade and the respective pressures at which coolant is provided to each coolant supply line from the moment that the wafer is seated on the wafer-cooling blade and moved.

In addition, a multi-chamber semiconductor device fabrication apparatus in accordance with an embodiment of the invention may comprise at least one fewer chamber than a conventional multi-chamber semiconductor device fabrication apparatus because a separate cool-down chamber for cooling wafers can be omitted from the multi-chamber semiconductor device fabrication apparatus. Consequently, a multi-chamber semiconductor device fabrication apparatus in accordance with an embodiment of the invention can provide advantages in the layout of the multi-chamber semiconductor device fabrication apparatus.

Also, because, in accordance with embodiments of the invention, a wafer on which a process has been performed can be cooled without a separate cooling process being performed on the wafer, the efficiency of the overall fabrication process performed by the multi-chamber semiconductor device fabrication apparatus can be improved markedly. Thus, the productivity of the multi-chamber semiconductor device fabrication apparatus can be improved.

Also, in accordance with embodiments of the invention, a wafer-cooling blade may spray coolant onto the upper surface of a wafer seated on the wafer-cooling blade in order to cool the wafer. In addition, spraying coolant onto the wafer may hold the wafer to the wafer-cooling blade more securely as the wafer-cooling blade moves than if the coolant were not sprayed onto the wafer. Spraying coolant onto the top of the wafer may also substantially prevent particles from contaminating the wafer. These benefits are very advantageous because the multi-chamber semiconductor device fabrication apparatus in accordance with an embodiment of the invention may have an increased yield relative to a conventional multi-chamber semiconductor device fabrication apparatus.

Although embodiments of the invention have been described herein, various modifications may be made to the embodiments by one of ordinary skill in the art without departing from the scope of the invention as defined by the accompanying claims.

What is claimed is:

1. A multi-chamber semiconductor device fabrication apparatus comprising:
a transfer chamber;
a plurality of outer chambers connected to the transfer chamber; and,
a wafer handling and cooling mechanism comprising a wafer-cooling blade adapted to support a wafer seated on the wafer-cooling blade, wherein:
the wafer handling and cooling mechanism is adapted to transfer the wafer seated on the wafer-cooling blade from an interior of the transfer chamber to a first outer chamber during a transfer period; and,
the wafer-cooling blade is adapted to actively cool the wafer seated on the wafer-cooling blade during the transfer period.

2. The apparatus of claim 1, wherein:
the wafer-cooling blade comprises:
a plurality of side surfaces and a plurality of extending parts, wherein the extending parts extend above the side surfaces, respectively; and,
a plurality of coolant spraying nozzles disposed in inner surfaces of the extending parts; and,
the wafer-cooling blade is adapted to actively cool the wafer seated on the wafer-cooling blade by spraying coolant onto an upper surface of the wafer seated on the wafer-cooling blade through the coolant spraying nozzles.

3. The apparatus of claim 2, wherein the coolant is gaseous.

4. The apparatus of claim 2, wherein:
the coolant spraying nozzles are disposed above the upper surface of the wafer seated on the wafer-cooling blade;
each coolant spraying nozzle is adapted to spray the coolant at a respective downward angle towards the wafer seated on the wafer-cooling blade;
each coolant spraying nozzle is adapted to spray the coolant on a respective wafer area of the wafer seated on the wafer-cooling blade; and,
at least two of the wafer areas overlap one another.

5. The apparatus of claim 2, wherein:
the wafer-cooling blade comprises a coolant flow line; and,
the coolant is provided to the coolant spraying nozzles through the coolant flow line.

6. The apparatus of claim 5, further comprising:
an apparatus controller;
a temperature sensor disposed in a portion of a non-continuous wafer seating surface of the wafer-cooling blade and adapted to provide a temperature signal to the apparatus controller; and,
a pump adapted to selectively provide the coolant to the coolant flow line and adapted to control a pressure at which the coolant is provided to the coolant flow line,
wherein the apparatus controller is adapted to control the pump in accordance with the temperature control signal.

7. The apparatus of claim 1, wherein:
the wafer handling and cooling mechanism is adapted to move the wafer seated on the wafer-cooling blade from a second outer chamber into the transfer chamber during a first portion of the transfer period;
the wafer-cooling blade is adapted to spray coolant onto the wafer seated on the wafer-cooling blade while the wafer seated on the wafer-cooling blade is in the transfer chamber during a second portion of the transfer period; and,
the wafer handling and cooling mechanism is adapted to transfer the wafer seated on the wafer-cooling blade into the first outer chamber during a third portion of the transfer period.

8. A multi-chamber semiconductor device fabrication apparatus comprising:
a transfer chamber;
a plurality of outer chambers connected to the transfer chamber; and, a wafer handling and cooling mechanism comprising a wafer-cooling blade adapted to support a wafer seated on the wafer-cooling blade, wherein:
the wafer handling and cooling mechanism is adapted to transfer the wafer seated on the wafer-cooling blade from an interior of the transfer chamber to a first outer chamber during a transfer period;
the wafer-cooling blade is adapted to actively cool the wafer seated on the wafer-cooling blade during the wafer transfer period; and,
the wafer-cooling blade comprises a bottom surface and a plurality of first coolant spraying nozzles disposed in the bottom surface.

9. The apparatus of claim 8, wherein:
the wafer-cooling blade further comprises:
a plurality of side surfaces and a plurality of extending parts, wherein the extending parts extend above the side surfaces, respectively; and,
a plurality of second coolant spraying nozzles disposed in inner surfaces of the extending parts;
the wafer-cooling blade is adapted to actively cool the wafer by spraying coolant onto a lower surface of the wafer seated on the wafer-cooling blade through the first coolant spraying nozzles and by spraying the coolant onto an upper surface of the wafer seated on the wafer-cooling blade through the second coolant spraying nozzles.

10. The apparatus of claim 9, wherein the coolant is gaseous.

11. The apparatus of claim 9, wherein:
the second coolant spraying nozzles are disposed above the upper surface of the wafer seated on the wafer-cooling blade;
each second coolant spraying nozzle is adapted to spray the coolant at a respective downward angle towards the wafer seated on the wafer-cooling blade;
each coolant spraying nozzle is adapted to spray the coolant on a respective wafer area of the wafer seated on the wafer-cooling blade; and,
at least two of the wafer areas overlap one another.

12. The apparatus of claim 9, wherein the wafer-cooling blade further comprises:
a first coolant flow line adapted to provide the coolant to the first plurality of coolant spraying nozzles; and,
a second coolant flow line adapted to provide the coolant to the second plurality of coolant spraying nozzles.

13. The apparatus of claim 12, further comprising:
an apparatus controller;
a temperature sensor disposed in a portion of a non-continuous wafer seating surface of the wafer-cooling blade and adapted to provide a temperature signal to the apparatus controller;
a first pump adapted to selectively provide the coolant to the first coolant flow line and adapted to control a first pressure at which the coolant is provided to the first coolant flow line; and,
a second pump adapted to selectively provide the coolant to the second coolant flow line and adapted to control a second pressure at which the coolant is provided to the second coolant flow line,
wherein the apparatus controller is adapted to control the first and second pumps in accordance with the temperature control signal.

14. The apparatus of claim 9, wherein the wafer-cooling blade is adapted to spray the coolant from the first coolant spraying nozzles at a first pressure and is adapted to spray the coolant from the second coolant spraying nozzles at a second pressure greater than the first pressure.

15. A multi-chamber semiconductor device fabrication apparatus comprising:
a transfer chamber;
a plurality of outer chambers connected to the transfer chamber; and,
a wafer handling and cooling mechanism comprising a wafer-cooling blade adapted to support a wafer seated on the wafer-cooling blade, wherein:
the wafer handling and cooling mechanism is adapted to transfer the wafer seated on the wafer-cooling blade from an interior of the transfer chamber to a first outer chamber during a transfer period;
the wafer-cooling blade is adapted to actively cool the wafer seated on the wafer-cooling blade during the wafer transfer period; and,
the wafer-cooling blade comprises a continuous wafer seating surface and a first coolant flow line disposed in the wafer-cooling blade below the continuous wafer seating surface,
wherein:
the wafer seated on the wafer-cooling blade is seated on the continuous wafer seating surface; and,
first coolant is circulated in the first coolant flow line to cool the continuous wafer seating surface and thereby actively cool the wafer seated on the wafer-cooling blade.

16. The apparatus of claim 15, wherein:
the wafer-cooling blade comprises:
a plurality of side surfaces and a plurality of extending parts, wherein the extending parts extend above the side surfaces, respectively; and,
a plurality of coolant spraying nozzles disposed in inner surfaces of the extending parts; and,
the wafer-cooling blade is adapted to further actively cool the wafer seated on the wafer-cooling blade by spraying second coolant onto an upper surface of the wafer seated on the wafer-cooling blade through the coolant spraying nozzles.

17. The apparatus of claim 16, wherein both the first and second coolants are gaseous.

18. The apparatus of claim 16, wherein the first coolant is liquid and the second coolant is gaseous.

19. The apparatus of claim 16, wherein:
the coolant spraying nozzles are disposed above the upper surface of the wafer seated on the wafer-cooling blade;
each coolant spraying nozzle is adapted to spray the coolant at a respective downward angle towards the upper surface of the wafer seated on the wafer-cooling blade;
each coolant spraying nozzle is adapted to spray the coolant on a respective wafer area of the wafer seated on the wafer-cooling blade; and,
at least two of the wafer areas overlap one another.

20. The apparatus of claim 16, further comprising:
an apparatus controller;
a temperature sensor disposed in the continuous wafer seating surface of the wafer-cooling blade and adapted to provide a temperature signal to the apparatus controller;
a first pump adapted to selectively provide the first coolant to the first coolant flow line and adapted to control a first pressure at which the first coolant is provided to the first coolant flow line; and,
a second pump adapted to selectively provide the second coolant to a second coolant flow line and adapted to control a second pressure at which the second coolant is provided to the second coolant flow line,
wherein:
the second coolant is provided to the coolant spraying nozzles through the second coolant flow line; and,
the apparatus controller is adapted to control the first and second pumps in accordance with the temperature control signal.
